(19) United States
(12) Patent Application Publication
(10) Pub. No.: US 2024/0068805 A1
(43) Pub. Date: Feb. 29, 2024

(54) DETECTION DEVICE AND DETECTION METHOD

(71) Applicant: LAPIS SEMICONDUCTOR CO., LTD., Kanagawa (JP)

(72) Inventor: ARATA NAGANUMA, KANAGAWA (JP)

(21) Appl. No.: 18/237,971

(22) Filed: Aug. 25, 2023

(30) Foreign Application Priority Data
Aug. 30, 2022 (JP) 2022-136758

(51) Int. Cl. G01B 11/27

(52) U.S. Cl. CPC G01B 11/272

(57) ABSTRACT

A detection device including: a laser sensor provided between a supply unit that supplies an inspection object and an inspection unit that inspects the inspection object; and a measurement unit that measures a state of the inspection object by using the laser sensor with respect to the inspection object moving along a transport direction from the supply unit toward the inspection unit.

### CROSS-REFERENCE TO RELATED APPLICATION

This application claims priority under 35 USC 119 from Japanese Patent Application No. 2022-136758, filed on Aug. 30, 2022, the disclosure of which is incorporated by reference herein.

### BACKGROUND

### Technical Field

The present disclosure relates to a detection device and a detection method.

### Related Art

Japanese Patent Application Laid-Open (JP-A) No. 2019-11961, discloses a transport device for an electronic component for detecting presence or absence of a component by emitting a laser beam to a component mounting unit.

However, the transport device disclosed in JP-A No. 2019-11961, cannot detect a positional misalignment of the electronic component mounted on the component mounting unit.

### SUMMARY

The present disclosure provides a detection device and a detection method that may detect a positional misalignment of an inspection object.

A first aspect of the present disclosure is a detection device including: a laser sensor provided between a supply unit that supplies an inspection object and an inspection unit that inspects the inspection object; and a measurement unit that measures a state of the inspection object by using the laser sensor with respect to the inspection object moving along a transport direction from the supply unit toward the inspection unit.

In accordance with the above aspect, the detection device according to the present disclosure may detect the positional misalignment while the inspection object is transported during inspection of the inspection object.

In accordance with the above aspect, the detection device according to the present disclosure may detect the positional misalignment of the inspection object.

### BRIEF DESCRIPTION OF THE DRAWINGS

Exemplary embodiments will be described in detail based on the following figures, wherein:

FIG. 1 is a block diagram illustrating a hardware configuration of an inspection apparatus and a detection device of an embodiment;

FIG. 2 is a diagram illustrating an internal configuration of a transport device of the embodiment;

FIG. 3A is a diagram illustrating a positional relationship between a transport container and a pusher in an inspection unit of the embodiment, and is a diagram illustrating a state in which there is no positional misalignment of an IC device;

FIG. 3B is a diagram illustrating the positional relationship between the transport container and the pusher in the inspection unit of the embodiment, and is a diagram illustrating a state in which the positional misalignment of the IC device has occurred;

FIG. 3C is a diagram illustrating the positional relationship between the transport container and the pusher in the inspection unit of the embodiment, and is a diagram illustrating a state in which the IC device in which the positional misalignment is caused is pressed by the pusher;

FIG. 4 is a diagram illustrating an attachment state of a sensor unit of the embodiment;

FIG. 5 is a block diagram illustrating a hardware configuration of an analysis device of the embodiment;

FIG. 6 is a block diagram illustrating a functional configuration of the analysis device of the embodiment;

FIG. 7 is an example of a scanned image by a detection device; and

FIG. 8 is a flowchart illustrating a flow of detection processing executed in the inspection apparatus of the embodiment.

### DETAILED DESCRIPTION

A detection device according to the present disclosure and an inspection apparatus in which the detection device is incorporated will be described. The inspection apparatus is an apparatus that inspects performance and functions of an electronic component, such as an IC device. The detection device has a function of detecting a positional misalignment of the IC device in the inspection apparatus. Hereinafter, an embodiment of the present disclosure will be described with reference to the drawings.

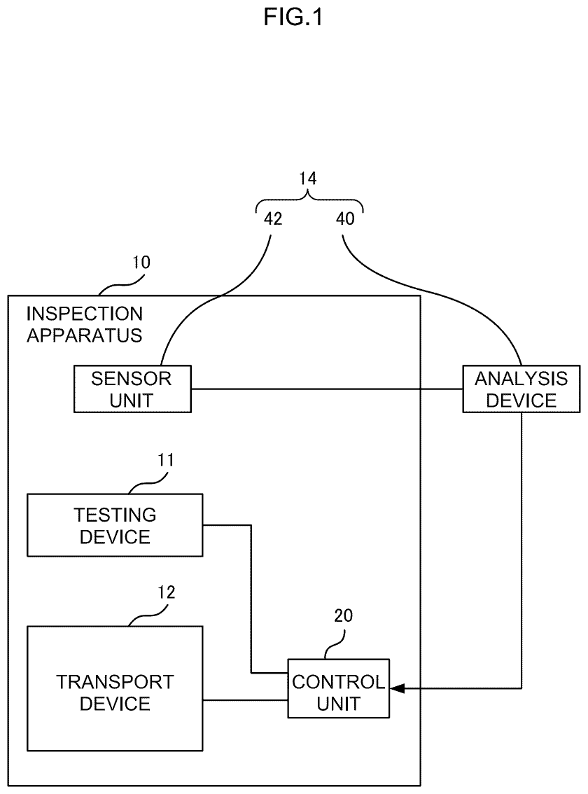

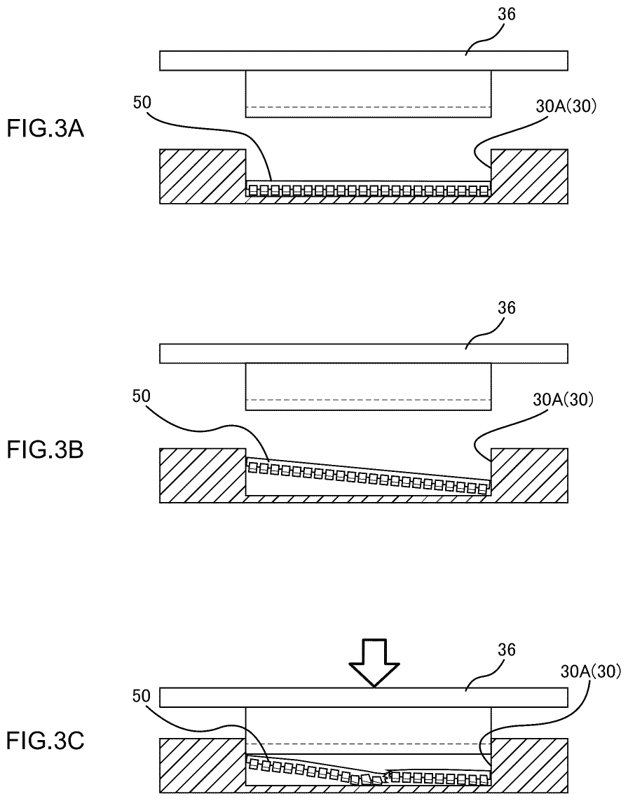

As illustrated in FIG. 1, an inspection apparatus 10 of the present embodiment includes a testing device 11, a transport device 12, and a control unit 20. The testing device 11 performs a performance test of an IC device 50 (see FIG. 3A) which is an inspection object. The transport device 12 transports the IC device 50 to be inspected toward an inspection unit 26 and takes out the IC device 50 from the inspection unit 26 for which the inspection has been completed. In the present embodiment, in the inspection unit 26, the IC device 50 is configured to be electrically connectable to the testing device 11.

The control unit 20 controls each of the testing device 11 and the transport device 12. A sensor unit 42 is provided inside the inspection apparatus 10. The sensor unit 42 configures a detection device 14 together with an analysis device 40 provided outside the inspection apparatus 10.

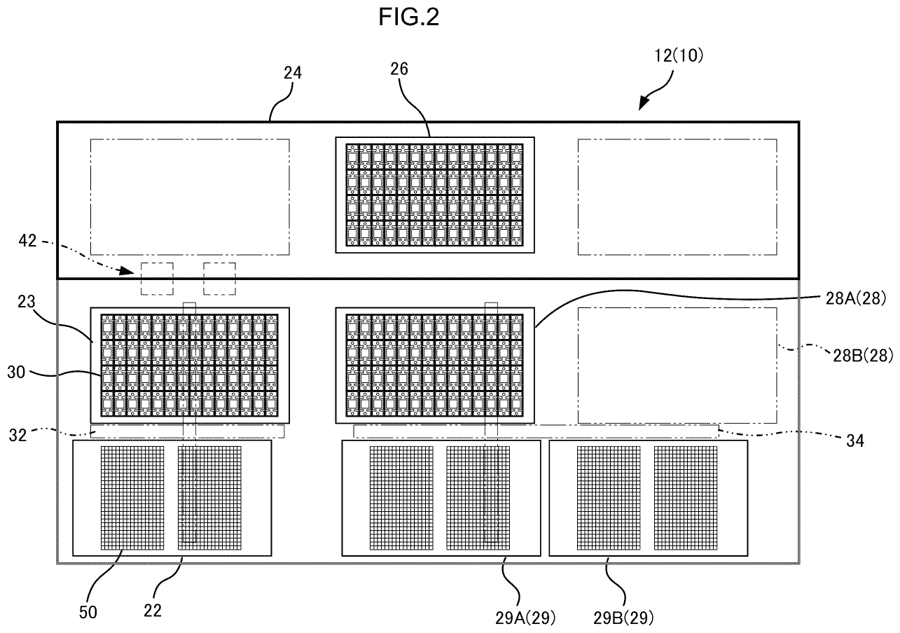

FIG. 2 illustrates an internal structure of the transport device 12 of the present embodiment. The transport device 12 includes, as a path through which the IC device 50 circulates, a supply unit 22, a workpiece insertion unit 23, a chamber 24, an inspection unit 26, a workpiece take-out unit 28, and a collection unit 29.

The supply unit 22 is a place where the IC device 50 to be inspected is on standby. In the supply unit 22, the IC device 50 is stored in a storage container (not illustrated).

The workpiece insertion unit 23 is a place of the supply unit 22 for inserting the IC device 50 into a transport container 30. The IC device 50 is transported from the supply unit 22 toward the workpiece insertion unit 23 by a supply robot 32 which is a pick-and-place device. Specifically, a plurality of IC devices 50 are taken out from the storage container of the supply unit 22 and are inserted into accommodation units 30A (see FIG. 3A) of the transport container 30 installed in the workpiece insertion unit 23.

The chamber 24 is a room in which a temperature control or the like is performed in order to inspect the IC device 50. The IC device 50 is transported from the workpiece insertion unit 23 toward the chamber 24 in a state of being accommodated in the transport container 30.

The inspection unit 26 is a space provided in the chamber 24 for setting the IC device 50 in the testing device 11. Here, a bottom surface side of the accommodation unit 30A of the transport container 30 is opened, the IC device 50 is held around the opening, and a terminal of the IC device 50 is exposed from the opening. When the transport container 30 reaches the inspection unit 26, a pusher 36 (see FIG. 3A) provided for each accommodation unit 30A descends from above and presses the IC device 50. Accordingly, the terminal of the IC device 50 protrudes from the opening of the accommodation unit 30A and is connected to a terminal at the testing device 11 side. Accordingly, the IC device 50 is electrically connected to the testing device 11, and a performance test is performed.

Here, in a case in which the IC device 50 is accommodated obliquely with respect to the accommodation unit 30A as illustrated in FIG. 3B, the pusher 36 descends and presses the IC device 50 as it is, and thus, the IC device 50 is damaged as illustrated in FIG. 3C. Thus, in the present embodiment, in order to prevent the IC device 50 from being damaged in the inspection unit 26, a positional misalignment is inspected during a period from when the IC device 50 is accommodated in the transport container 30 until when the IC device 50 reaches the inspection unit 26.

As illustrated in FIG. 2, the workpiece take-out unit 28 is a place where the IC device 50 is taken out from the transport container 30 taken out from the chamber 24. The workpiece take-out unit 28 includes a first take-out unit 28A corresponding to a first collection unit 29A and a second take-out unit 28B corresponding to a second collection unit 29B.

The collection unit 29 is a place where the IC device 50 taken out from the transport container 30 is collected. The collection unit 29 includes a first collection unit 29A that collects a non-defective IC device 50 and a second collection unit 29B that collects a defective IC device 50. The IC device 50 is transported from the workpiece take-out unit 28 toward each collection unit 29 by a collection robot 34 that is a pick-and-place device. Specifically, the non-defective IC device 50 is taken out from the transport container 30 in the first take-out unit 28A and is inserted into the storage container installed in the first collection unit 29A. The defective IC device 50 is taken out from the transport container 30 in the second take-out unit 28B and is inserted into the storage container installed in the second collection unit 29B.

An empty transport container 30 from which the IC device 50 has been taken out moves from the workpiece take-out unit 28 to the workpiece insertion unit 23, and the IC device 50 is stored again.

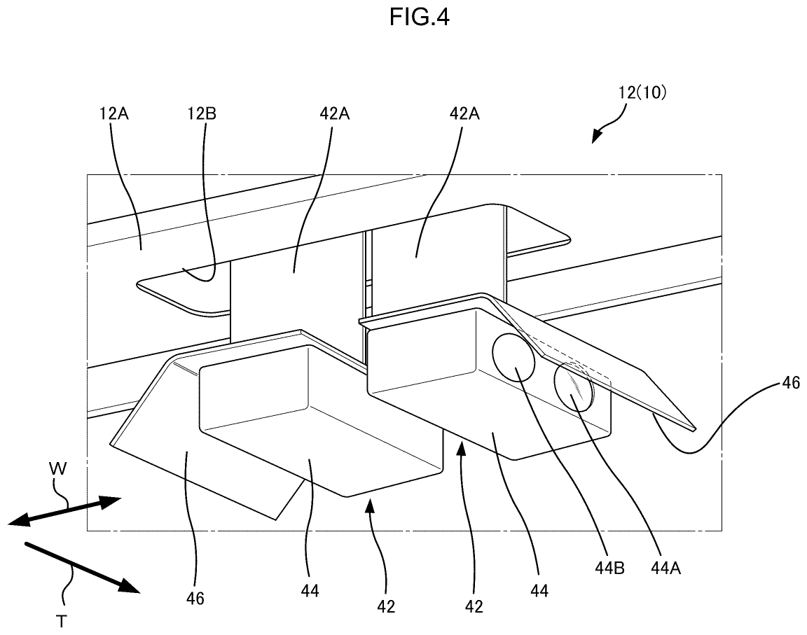

Here, in the present embodiment, a pair of sensor units 42 as components of the detection device 14 are provided between the workpiece insertion unit 23 and the chamber 24. As illustrated in FIG. 4, the pair of sensor units 42 are fixed by stays 42A extending downward from an opening 12B provided at a ceiling portion 12A of the transport device 12.

As illustrated in FIG. 1, the detection device 14 includes the analysis device 40 and the sensor unit 42. As illustrated in FIG. 4, each of the pair of sensor units 42 is fixed at the ceiling portion 12A of the transport device 12 by the stay 42A. Each sensor unit 42 includes a laser sensor 44 and a mirror 46. The laser sensor 44 is a sensor that scans the transport container 30 transported from the workpiece insertion unit 23 toward the chamber 24. The laser sensor 44 includes an irradiation unit 44A that emits a laser beam and a light receiving unit 44B that receives the laser beam reflected from the transport container 30. The laser sensor 44 of the present embodiment has a rectangular parallelepiped shape, and is installed in a lying state such that the irradiation unit 44A and the light receiving unit 44B face a lateral side of a main body.

Here, in a case in which the laser sensor 44 is installed such that the irradiation unit 44A and the light receiving unit 44B face a lower side of the transport device 12, the amount of protrusion of the transport device 12 from the ceiling portion 12A becomes large, compared to a case in which the laser sensor 44 is installed in the lying state as illustrated in FIG. 4. In such case, the supply robot 32 may interfere with the laser sensor 44. In contrast, in the present embodiment, since the laser sensor 44 is installed in the lying state, it is possible to avoid the interference with the supply robot 32.

In this regard, the laser sensor 44 is installed in the lying state, and thus, the laser beam cannot be directly emitted to the transport container 30. Thus, in the present embodiment, the mirror 46 is provided at a position on a lateral side facing the irradiation unit 44A and the light receiving unit 44B. The mirror 46 is fixed to the stay 42A at an angle of 45 degrees with respect to the workpiece insertion unit 23 and a floor surface of the chamber 24.

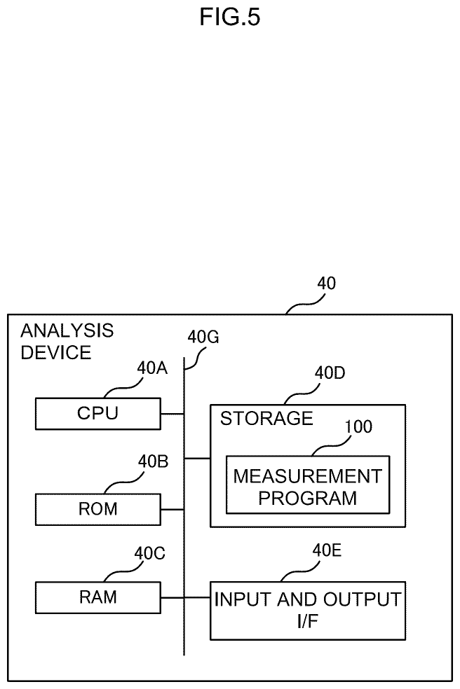

As illustrated in FIG. 5, the analysis device 40 of the present embodiment includes a central processing unit (CPU) 40A, a read only memory (ROM) 40B, a random access memory (RAM) 40C, a storage 40D, and an input and output interface (I/F) 40E. The CPU 40A, the ROM 40B, the RAM 40C, the storage 40D, and the input and output I/F 40E are connected to communicate with each other via an internal bus 40G.

The CPU 40A which is a processor is a central processing unit, and executes various programs and controls each unit. That is, the CPU 40A reads the program from the ROM 40B and the storage 40D, and executes the program with the RAM 40C as a work area.

The ROM 40B stores various programs and various kinds of data. The RAM 40C temporarily stores a program or data as a work area.

The storage 40D includes a hard disk drive (HDD) or a solid state drive (SSD). The storage 40D of the present embodiment stores a measurement program 100. The measurement program 100 is a program for measuring the positional misalignment of the IC device 50 accommodated in each accommodation unit 30A of the transport container 30. The measurement program 100 may be stored in the ROM 40B instead of the storage 40D.

The input and output I/F 40E is an interface for being connected to an external device. The input and output I/F 40E is connected to the laser sensor 44 and the control unit 20 of the inspection apparatus 10.

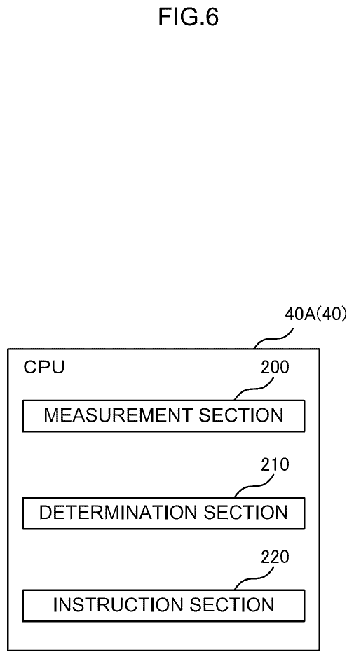

As illustrated in FIG. 6, in the analysis device 40 of the present embodiment, the CPU 40A functions as a measurement section 200, a determination section 210, and an instruction section 210 by executing the measurement program 100.

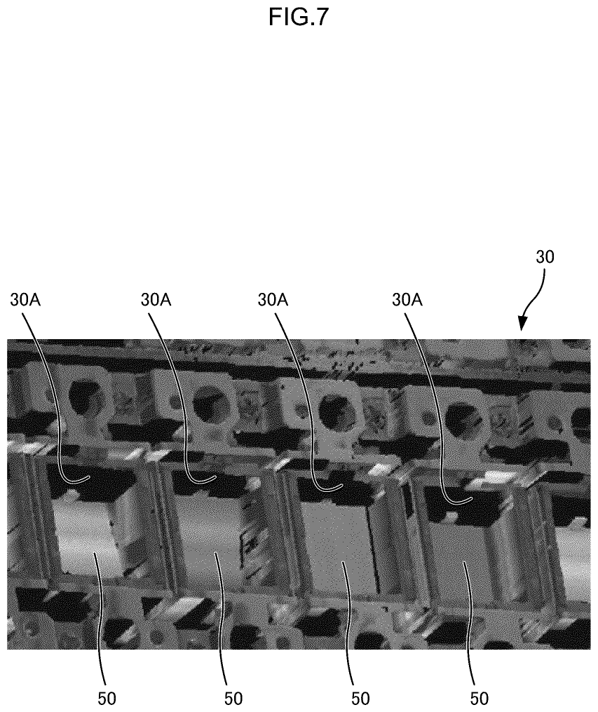

The measurement section 200 measures a state of the IC device 50 stored in the transport container 30 from a scanning result by the laser sensor 44. In particular, the measurement section 200 of the present embodiment displays the measured height with respect to a reference height in color, in a scanned image of the scanned transport container 30. For example, as illustrated in FIG. 7, it is possible to indicate the measured height, which is the state of the IC device 50 in the accommodation unit 30A, by expressing the reference height in blue and expressing a place higher than the reference height in red. Here, the “reference height” is an example of a “predetermined position”.

The determination section 210 determines whether or not the positional misalignment is caused in the IC device 50 stored in the transport container 30, based on the measurement result of the measurement section 200. Specifically, in a case in which the IC device 50 is positioned near the reference height, the determination section 210 determines that the positional misalignment is not caused in the IC device 50. In this regard, in a case in which the IC device 50 is not positioned near the reference height, the determination section 210 determines that the positional misalignment is caused in the IC device 50. Here, a case in which the IC device 50 is not completely accommodated and floats in the accommodation unit 30A and a case in which the IC device 50 is accommodated in an inclined manner with respect to the accommodation unit 30A, are illustrated as a case in which the IC device 50 is not positioned near the reference height.

In a case in which the determination section 210 determines that the positional misalignment is caused in the IC device 50, the instruction section 210 has a function of stopping the transport of the transport container 30. Specifically, in a case in which the determination section 210 determines that the positional misalignment is caused in the IC device 50, the instruction section 210 transmits a stop command to the control unit 20 included in the inspection apparatus 10. The control unit 20 that has received the stop command stops an operation of the transport device 12. In addition to the fact that the transport of the transport container 30 is stopped, an operation of the pusher 36 may be stopped.

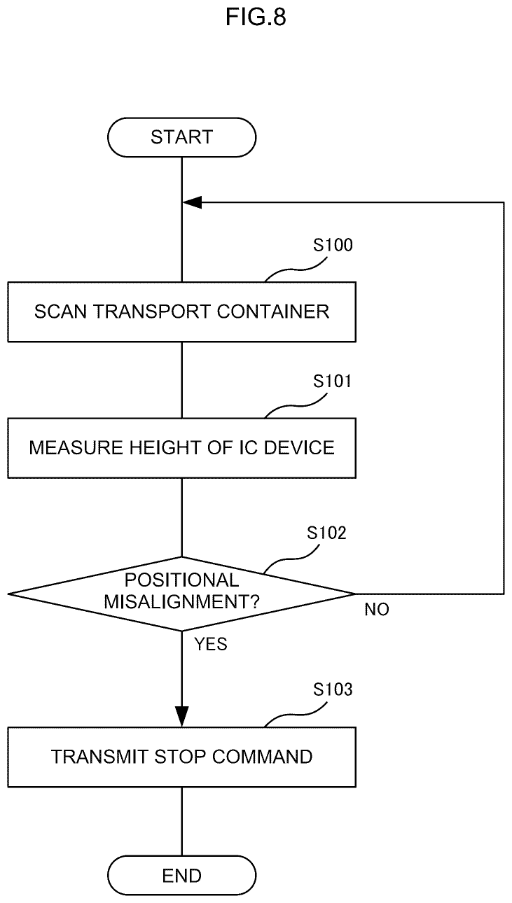

A flow of detection processing, which is a detection method executed by the detection device 14 of the present embodiment, will be described with reference to a flowchart of FIG. 8. The detection processing is executed by the CPU 40A of the analysis device 40 functioning as the measurement section 200, the determination section 210, and the instruction section 210 described above.

In step S100 of FIG. 8, the CPU 40A scans the transport container 30. Specifically, the CPU 40A generates a scanned image as illustrated in FIG. 7 by scanning the laser sensor 44 along a width direction (see an arrow W in FIG. 4) of the transport device 12 and transporting the transport container 30 along a transport direction (see an arrow T in FIG. 8).

In step S101, the CPU 40A measures a height of the IC device 50 in the scanned image. That is, the height of each part of the IC device 50 with respect to the reference height is measured from a color of the scanned image.

In step S102, the CPU 40A determines whether or not the positional misalignment is caused in the IC device 50. In a case in which the CPU 40A determines that the positional misalignment is caused in the IC device 50 (YES in step S102), the processing proceeds to step S103. In this regard, in a case in which the CPU 40A determines that the positional misalignment is not caused in the IC device 50 (NO in step S102), the processing returns to step S100.

In step S103, the CPU 40A transmits the stop command to the control unit 20 of the transport device 12. Accordingly, the transport of the transport container 30 is stopped. Then, the CPU 40A ends the detection processing.

The detection device 14 of the present embodiment includes the laser sensor 44 between the supply unit 22 that supplies the IC device 50 that is the inspection object and the inspection unit 26, specifically, between the workpiece insertion unit 23 and the chamber 24. The measurement section 200 that measures the state of the IC device 50 by using the laser sensor 44 with respect to the IC device 50 moving along a transport direction T from the supply unit 22 toward the chamber 24.

In accordance with the present embodiment, the detection device 14 may detect the positional misalignment while the IC device 50 is transported during the inspection of the IC device 50.

In particular, the measurement section 200 of the present embodiment emits the laser beam to the IC device 50 moving along the transport direction T from the laser sensor 44, and measures the height of each part of the IC device 50 with respect to the reference height.

Thus, in accordance with the present embodiment, it is possible to grasp the state of the IC device 50 in the accommodation unit 30A, such as a case in which the IC device 50 is not completely accommodated and floats in the accommodation unit 30A and a case in which the IC device 50 is accommodated obliquely with respect to the accommodation unit 30A.

In the inspection apparatus 10 (transport device 12) of the present embodiment, the laser sensor 44 is disposed such that a width and a depth are wider than a height along a vertical direction. In particular, the detection device 14 of the present embodiment can be installed later to the present existing inspection apparatus 10. Generally, it is difficult to secure a space for installing the laser sensor 44 inside the transport device 12. However, in the present embodiment, since the laser sensor 44 is disposed in the lying state, the inspection apparatus 10 of the present embodiment may avoid the interference with the supply robot 32.

The present embodiment includes the mirror 46 adjacent to the laser sensor 44 and reflects the laser beam emitted to the lateral side from the laser sensor 44 to be directed to the IC device 50. In accordance with the present embodiment, the mirror 46 is provided, and thus, the laser beam may be emitted downward even though the laser sensor 44 is in the lying state.

In the present embodiment, in a case in which a positional relationship between the portions of the IC device 50 with respect to the reference height measured by the measurement section 200 satisfies a predetermined condition, the movement of the IC device 50 in the transport direction T is stopped. Here, examples of the predetermined condition include a case in which the positional misalignment is caused in the IC device 50, such as a case in which the IC device 50 is not completely accommodated and floats in the accommodation unit 30A, and a case in which the IC device 50 is accommodated obliquely with respect to the accommodation unit 30A. In accordance with the present embodiment, it is possible to prevent the IC device 50 from being transported to the inspection unit 26 in a state where the positional misalignment is caused in the IC device 50, and to prevent the IC device 50 from being damaged in the inspection unit 26.

As described above, the detection device 14 of the present embodiment may be installed later with respect to the present existing inspection apparatus 10. In such case, Modifications of hardware and software by a manufacturer of the inspection apparatus 10 may be difficult. However, in accordance with the present embodiment, the detection device 14 may be installed later while the function of the existing device is maintained. The transport device 12 is stopped by detecting the positional misalignment of the IC device 50. Thus, the destruction of the IC device 50 may be suppressed.

In the above embodiment, although the sensor unit 42 of the detection device 14 is provided at a boundary between the workpiece insertion unit 23 and the chamber 24, the present disclosure is not limited thereto. The installation place of the sensor unit 42 is not limited as long as the installation place is on a path from the supply unit 22 to the inspection unit 26. The installation place can be determined in accordance with the structure of the transport device 12 in which the sensor unit 42 is installed. As long as the laser beam can be emitted to the transport container 30 on the path from the supply unit 22 to the inspection unit 26, the sensor unit 42 may be installed outside the transport device 12.

In the above embodiment, various kinds of processing executed by the CPU 40A reading software (program) may be executed by various processors other than the CPU. Examples of the processor in this case include a programmable logic device (PLD), which is a processor capable of changing a circuit configuration after manufacturer, such as a field-programmable gate array (FPGA), and a dedicated electric circuit, which is a processor having a circuit configuration specifically designed in order to execute specific processing such as an application specific integrated circuit (ASIC). Each processing described above may be executed by one of these various processors, or may be executed by a combination of two or more processors of the same type or different types (for example, any combination of a plurality of FPGAs or any combination of a CPU and an FPGA). More specifically, a hardware configuration of these various processors is an electric circuit in which circuit elements such as semiconductor elements are combined.

In the above embodiment, each program is stored (installed) in advance in a computer-readable non-transitory recording medium. For example, the measurement program 100 in the analysis device 40 is stored in advance in the storage 40D. However, the present disclosure is not limited thereto, and each program may be provided in a form recorded in a non-transitory recording medium such as a compact disc read only memory (CD-ROM), a digital versatile disc read only memory (DVD-ROM), and a universal serial bus (USB) memory. The program may be downloaded from an external device via a network.

The flow of the processing described in the above embodiment is an example, and unnecessary steps may be deleted, new steps may be added, or the processing order may be changed without departing from the gist.

What is claimed is:

1. A detection device comprising:
a laser sensor provided between a supply unit that supplies an inspection object and an inspection unit that inspects the inspection object; and
a measurement unit that measures a state of the inspection object by using the laser sensor with respect to the inspection object moving along a transport direction from the supply unit toward the inspection unit.

2. The detection device according to claim 1, wherein the measurement unit emits a laser beam from the laser sensor to the inspection object moving along the transport direction, and measures a height of each part of the inspection object with respect to a predetermined position.

3. The detection device according to claim 1, wherein the laser sensor is disposed such that its width and its depth are wider than its height in a vertical direction.

4. The detection device according to claim 3, further comprising a mirror that is adjacent to the laser sensor and that reflects the laser beam emitted to a lateral side from the laser sensor toward the inspection object.

5. The detection device according to claim 2, wherein, in a case in which a positional relationship, between portions of the inspection object with respect to the predetermined position measured by the measurement unit, satisfies a predetermined condition, movement of the inspection object in the transport direction is stopped.

6. A detection method, comprising, by a computer, executing processing of:
moving an inspection object along a transport direction toward an inspection unit that inspects the inspection object from a supply unit that supplies the inspection object; and
measuring a state of the inspection object by using a laser sensor provided between the supply unit and the inspection unit with the moving inspection object.
